(19) United States
(12) Patent Application Publication
(10) Pub. No.: US 2004/0246772 A1
(43) Pub. Date: Dec. 9, 2004

(54) Method and semiconductor integrated circuit for detecting soft defects in static memory cell

(75) Inventor: Chan-ho Lee, Osan-si (KR)

Correspondence Address: Steven M. Mills, MILLS & ONELLO LLP, Suite 605, Eleven Beacon Street, Boston, MA, 02108, US

(73) Assignee: Samsung Electronics Co., Ltd.

(21) Appl. No.: 10/858,984

(22) Filed: Jun. 2, 2004

(30) Foreign Application Priority Data
Jun. 4, 2003 (KR) 03-35905

(51) Int. Cl. G11C 11/00

(52) U.S. Cl. 365/154

(57) ABSTRACT

Provided are a semiconductor integrated circuit including a unit for detecting soft defects in a pull-down circuit of a static memory cell, and a method of detecting soft defects. The semiconductor integrated circuit includes a static memory cell, a bit line connected to a first node of the static memory cell and a complementary bit line connected to a second node of the static memory cell, and a current supply unit connected to the bit line and the complementary bit line to supply current to the bit line and the complementary bit line in response to a test signal during a test mode. Accordingly, a voltage difference between the bit line and the complementary bit line during a read operation of the test mode is smaller than that during a read operation of a normal mode. When a failure occurs after the read operation is performed under this test mode condition, it is determined that the semiconductor integrated circuit having the failure is vulnerable to soft defects.

### BACKGROUND OF THE INVENTION

This application claims the priority of Korean Patent Application No. 2003-35905, filed on Jun. 4, 2003, in the Korean Intellectual Property Office, the contents of which are incorporated herein in their entirety by reference.

1. Field of the Invention

The present invention relates to a semiconductor integrated circuit, and more particularly, to a semiconductor integrated circuit comprising a unit which detects soft defects in a static memory cell, and a method of detecting soft defects.

2. Description of the Related Art

Many complementary metal oxide semiconductor (CMOS) static random access memories (SRAMs) utilize four transistors per memory cell. However, due to some advantages, a six transistor cell approach is gaining in popularity. These advantages include higher operational stability, higher alpha-particle immunity, and a simpler process.

A primary disadvantage of the six transistor memory cell CMOS SRAM is that open circuit failures in a pull-up circuit of the memory cell can appear as soft defects. Because such faults do not result in a hard failure, testing and failure analysis have proven particularly difficult. A method of testing a CMOS SRAM device for soft defects in a pull-up circuit is disclosed in U.S. Pat. No. 5,361,232.

Soft defects can also occur in a pull-down circuit of the cell. Because the soft defects occurring in the pull-down circuit do not result in a hard failure in a similar fashion to the soft defects of the pull-up circuit, conventional testing technologies have failed to detect all soft defects in the pull-down circuit.

FIG. 1 is a schematic diagram of a modeling circuit of a conventional six transistor static memory cell. FIG. 2 is a schematic diagram of a semiconductor integrated circuit including a plurality of static memory cells shown in FIG. 1.

Referring to FIG. 1, in the six transistor static memory cell, resistors R1, R2 and R3 are located between a power voltage VDD and pull-up transistors MP1 and MP2, and resistors R4 and R5 are located between the pull-up transistors MP1 and MP2 and internal nodes D and DB. Resistors R8, R9 and R10 are located between a ground voltage VSS and pull-down transistors MN3 and MN4, and resistors R6 and R7 are located between the pull-down transistors MN3 and MN4 and the internal nodes D and DB. In general, the pull-up transistors MP1 and MP2 act as load transistors and the pull-down transistors MN3 and MN4 act as drive transistors.

Referring to the circuit diagram of FIG. 2, during a read operation, when a precharge signal PCH is initially at a logic “L”, PMOS transistors 211, 213, and 215 within a precharge circuit 21 are turned on and a bit line BIT and a complementary bit line BITB are precharged to a power voltage VDD.

Next, when the precharge signal PCH is at a logic “H” and accordingly, the PMOS transistors 211, 213, 215 within the precharge circuit 21 are turned off and one of word lines WL1 through WLn is activated to a logic “H”, one of memory cells M1 through Mn is selected and data D and complementary data DB stored in the selected memory cell are output to the bit line BIT and the complementary bit line BITB, respectively.

After a suitable time delay, a sense enable signal SAEN is activated to a logic “H”, and a sensor amplifier 23 senses and amplifies a voltage difference between the bit line BIT and the complementary bit line BITB and outputs the results as output data.

Even if the selected memory cell is not defective during a test mode, if the soft defects occur in a pull-down circuit of the memory cell while the semiconductor integrated circuit is mounted, that is, employed in a system, in other words, if the resistances of the resistors R6 through R10 within the pull-down circuit of the memory cell increase for some reason, a voltage difference between the bit line BIT and the complementary bit line BITB may be smaller than an offset voltage of a sense amplifier 23. In this case, the sense amplifier malfunctions and functional failure occurs.

Since the soft defects occurring in the pull-down circuit of the memory cell do not result in a hard failure as described above, the conventional testing technologies cannot accurately detect the soft defects in the pull-down circuit. Thus, an apparatus and method for predicting and detecting soft defects in a pull-down circuit of a memory cell is required.

### SUMMARY OF THE INVENTION

The present invention provides a semiconductor integrated circuit including a unit for detecting soft defects in a pull-down circuit of a static memory cell.

The present invention also provides a method of detecting soft defects in a pull-down circuit of a static memory cell.

According to an aspect of the present invention, there is provided a semiconductor integrated circuit comprising: a static memory cell; a bit line connected to a first node of the static memory cell; a complementary bit line connected to a second node of the static memory cell; and a current supply unit, connected to the bit line and the complementary bit line, which supplies current to the bit line and the complementary bit line in response to a test signal during a test mode.

The semiconductor integrated circuit may further comprise: a precharge circuit, connected to the bit line and the complementary bit line, which precharges the bit line and the complementary bit line in response to a precharge signal; and a sense amplifier, connected to the bit line and the complementary bit line, which senses and amplifies a voltage difference between the bit line and the complementary bit line in response to a sense enable signal.

The current supply unit may include: a first current source, connected between a power voltage and the bit line, which supplies current to the bit line in response to the test signal; and a second current source, connected between a power voltage and the complementary bit line, which supplies current to the complementary bit line in response to the test signal.

The first current source and the second current source may include a PMOS transistor. The PMOS transistor of the first current source may have a source to which the power voltage is applied, a gate to which the test signal is input, and a drain connected to the bit line The PMOS transistor of the second current source may have a source to which the power voltage is applied, a gate to which the test signal is input, and a drain connected to the complementary bit line.

According to another aspect of the present invention, there is provided a method of detecting soft defects in a static memory cell of a semiconductor integrated circuit including a static memory cell selected by activation of a word line, a bit line connected to a first node of the static memory cell, and a complementary bit line connected to a second node of the static memory cell, the method comprising: precharging the bit line and the complementary bit line; supplying current to the bit line and the complementary bit line in response to a test signal during a test mode; activating the word line; and sensing and amplifying a voltage difference between the bit line and the complementary bit line in response to a sense enable signal.

When defects occur in the voltage difference sensing and amplifying step, it may be determined that the memory cell is vulnerable to soft defects.

### BRIEF DESCRIPTION OF THE DRAWINGS

The foregoing and other features and advantages of the invention will be apparent from the more particular description of an embodiment of the invention, as illustrated in the accompanying drawing. The drawing is not necessarily to scale, emphasis instead being placed upon illustrating the principles of the invention.

FIG. 1 is a schematic diagram of a modeling circuit of a conventional six transistor static memory cell.

FIG. 2 is schematic diagram of a semiconductor integrated circuit including the static memory cells shown in FIG. 1.

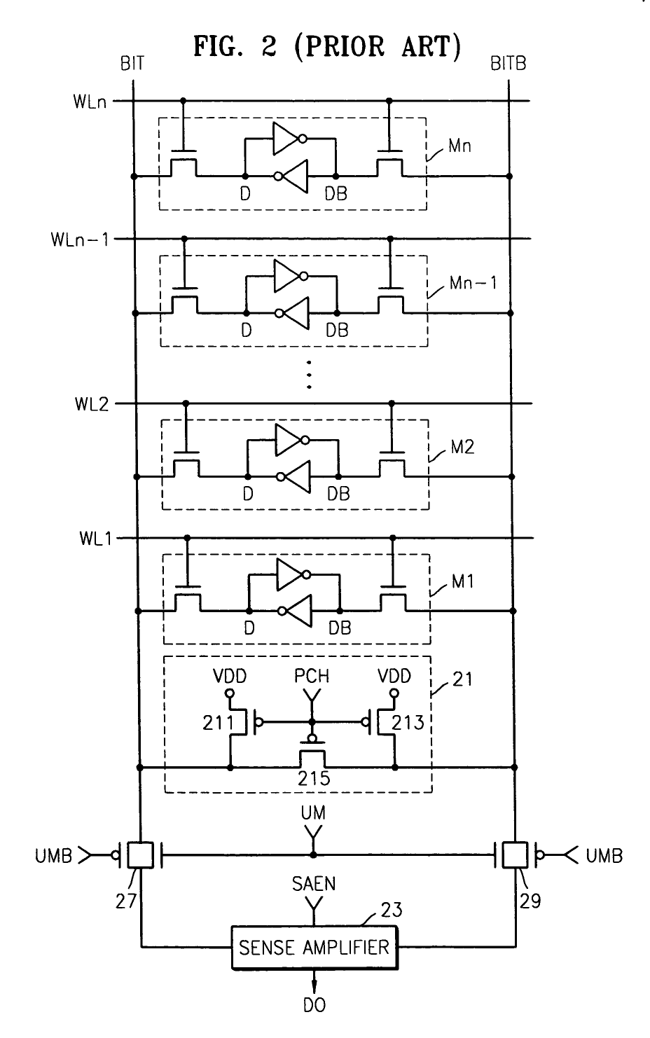

FIG. 3 is a schematic diagram of a semiconductor integrated circuit including a unit for detecting soft defects according to an embodiment of the present invention.

FIG. 4 is a timing diagram of a read operation of a memory cell without soft defects in the semiconductor integrated circuit of FIG. 3.

FIG. 5 is a timing diagram of a read operation of a memory cell with soft defects in the semiconductor integrated circuit of FIG. 3.

### DETAILED DESCRIPTION OF THE INVENTION

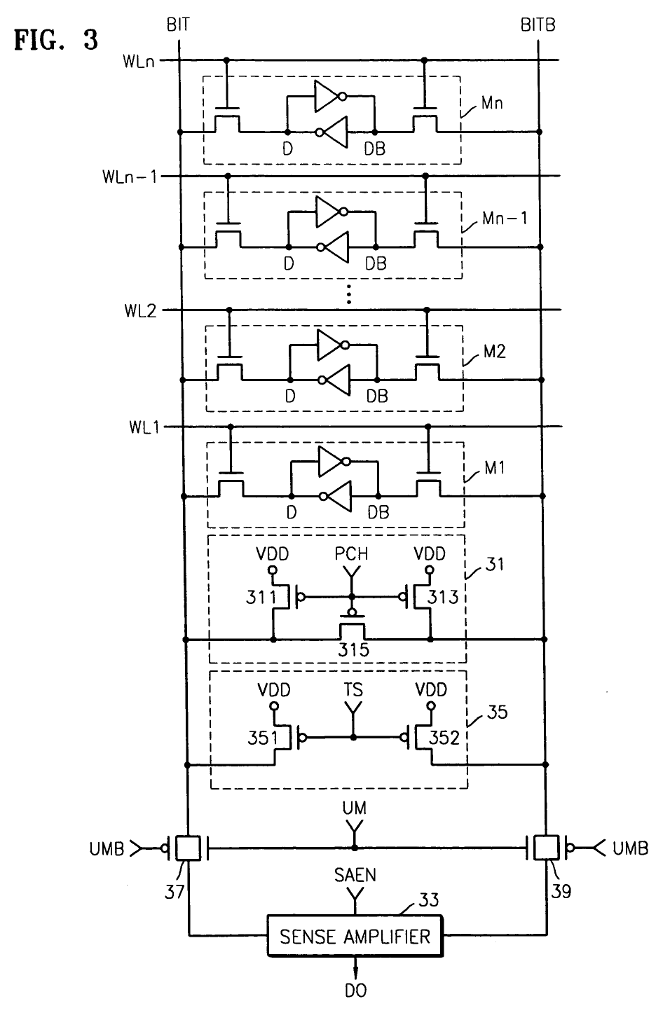

FIG. 3 is a schematic diagram of a semiconductor integrated circuit including a unit for detecting soft defects according to an embodiment of the present invention.

Referring to FIG. 3, the semiconductor integrated circuit includes a plurality of static memory cells M1 through Mn, a bit line BIT, a complementary bit line BITB, a pre-charge circuit 31, switches 37 and 39, and a sense amplifier 33. In particular, the semiconductor integrated circuit of the present embodiment further includes a current supply unit 35.

One node of each of the static memory cells M1 through Mn is connected to the bit line BIT, and another node of each of the static memory cells M1 through Mn is connected to the complementary bit line BITB. The pre-charge circuit 31 is connected to the bit line BIT and the complementary bit line BITB, and precharges the bit line BIT and the complementary bit line BITB in response to a pre-charge signal PCH.

The switches 37 and 39 control connections between the bit line BIT and the complementary bit line BITB and the sense amplifier 33 in response to a control signal UM. While the switches 37 and 39 are turned on, the sense amplifier 33 senses and amplifies a voltage difference between the bit line BIT and the complementary bit line BITB in response to a sense enable signal SAEN.

In particular, the current supply unit 35 is connected to the bit line BIT and the complementary bit line BITB, and supplies DC current to the bit line BIT and the complementary bit line BITB in response to a test signal TS during a test mode.

The current supply unit 35 includes a first current source 351 connected between a power voltage VDD and the bit line BIT to supply current to the bit line in response to the test signal TS, and a second current source 352 connected between the power voltage VDD and the complementary bit line BITB to supply current to the complementary bit line BITB in response to the test signal TS.

Here, the first current source 351 includes a PMOS transistor having a source to which the power voltage VDD is input, a gate to which the test signal TS is input, and a drain connected to the bit line BIT. The second current source 352 includes a PMOS transistor having a source to which the power voltage VDD is applied, a gate to which the test signal TS is input, and a drain connected to the complementary bit line BITB.

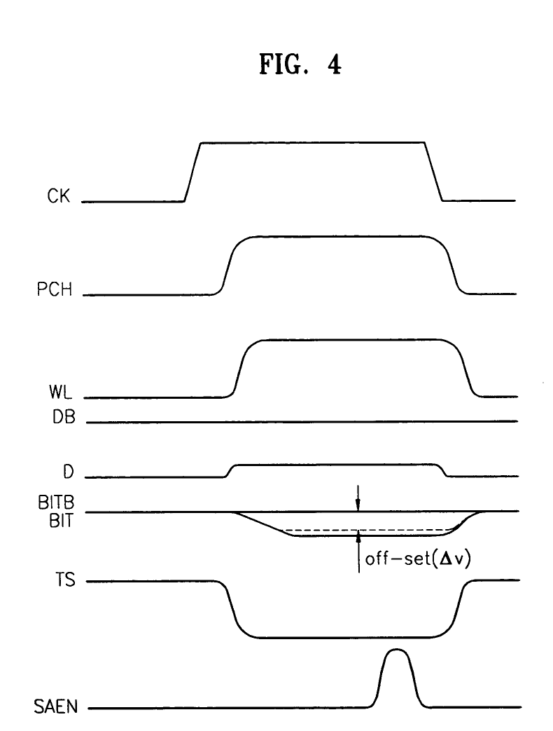

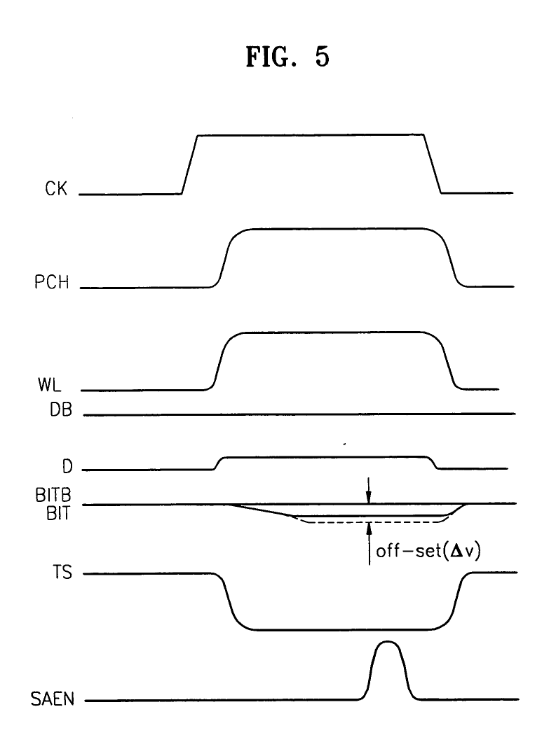

FIG. 4 is a timing diagram of a read operation of a memory cell without soft defects in the semiconductor integrated circuit of FIG. 3. FIG. 5 is a timing diagram of a read operation of a memory cell with soft defects in the semiconductor integrated circuit of FIG. 3.

A method of detecting soft defects in pull-down circuits of the static memory cells Ml through Mn in FIG. 3 will be described in detail with reference to FIGS. 4 and 5.

When the pre-charge signal PCH is initially at a logic “L” during a read operation in the circuit of FIG. 3, PMOS transistors 311, 313, and 315 within the pre-charge circuit 31 are turned on, and thus the bit line BIT and the complementary bit line BITB are pre-charged to a power voltage VDD.

Next, when the pre-charge signal PCH is at a logic “H”, the PMOS transistors 311, 313, 315 within the pre-charge circuit 31 are turned off, and one of a plurality of word lines WL1 through WLn is activated to a logic “H”, data D and complementary data DB stored in a selected memory cell are output to the bit line BIT and the complementary bit line BITB, respectively.

After a sufficient time delay, the sense enable signal SAEN is activated to a logic “H”, and the sense amplifier 33 senses and amplifies a voltage difference between the bit line BIT and the complementary bit line BITB, and outputs the result as output data DO.

At this time, if soft defects do not occur in a pull-down circuit of the selected memory cell, the voltage difference between the bit line BIT and the complementary bit line BITB is larger than an offset voltage ΔV of the sense amplifier 33 as shown in FIG. 4. Therefore, the sense amplifier 33 can sense and amplify the voltage difference between the bit line BIT and the complementary bit line BITB without errors.

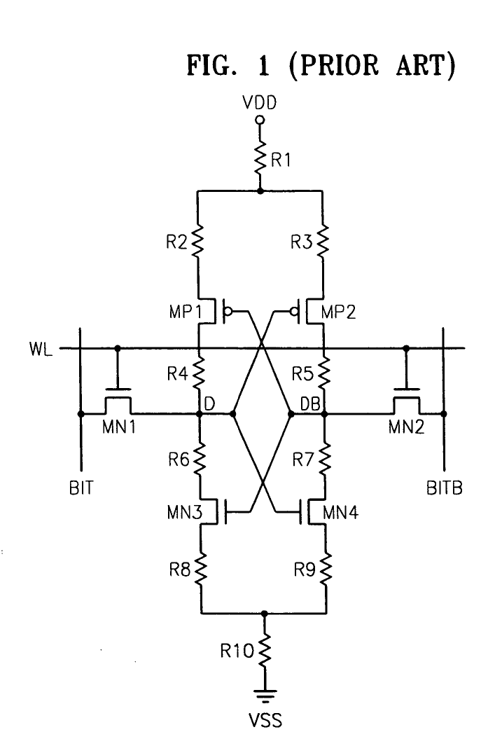

Although the selected memory cell is not defective during the test mode, if the soft defects occur in the pull-down circuit of the memory cell while the semiconductor integrated circuit is mounted, that is, employed in a system, that is, if the resistances of the resistors R6 through R10 (see FIG. 1) within the pull-down circuit of the memory cell increase for some reason, the voltage difference between the bit line BIT and the complementary bit line BITB may be smaller than the offset voltage ΔV of the sense amplifier 23. In this case, the sense amplifier malfunctions and function failure occurs.

Accordingly, to screen a semiconductor integrated circuit including memory cells vulnerable to soft defects in advance, the present invention further includes the current supply unit 35 which is controlled by the test signal TS. The current supply unit 35 supplies DC current to the bit line BIT and the complementary bit line BITB in response to the test signal TS during the test mode.

That is to say, when the test signal TS is activated to a logic “L” during a read operation of the test mode, the PMOS transistors 351 and 352 within the current supply unit 35 are turned on and accordingly, DC current is supplied to the bit line BIT and the complementary bit line BITB. As a consequence, the voltage difference between the bit line BIT and the complementary bit line BITB during the read operation of the test mode is smaller than that during a read operation of a normal mode.

When a fail occurs after the read operation is performed under this test mode condition, it is determined that the semiconductor integrated circuit having the failure is vulnerable to soft defects, and the semiconductor integrated circuit is screened in advance. Since only semiconductor integrated circuits without any failure, that is to say, semiconductor integrated circuits highly resistant to soft defects, are provided to customers, function failure at a mounting stage is prevented.

As described above, the semiconductor integrated circuit according to the present invention includes a circuit for detecting soft defects in the pull-down circuit of the static memory cell, and accordingly, the soft defects can be easily detected during the test.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor integrated circuit comprising:
a static memory cell;
a bit line connected to a first node of the static memory cell;
a complementary bit line connected to a second node of the static memory cell; and
a current supply unit, connected to the bit line and the complementary bit line, which supplies current to the bit line and the complementary bit line in response to a test signal during a test mode.

2. The semiconductor integrated circuit of claim 1, further comprising:
a precharge circuit, connected to the bit line and the complementary bit line, which precharges the bit line and the complementary bit line in response to a precharge signal; and
a sense amplifier, connected to the bit line and the complementary bit line, which senses and amplifies a voltage difference between the bit line and the complementary bit line in response to a sense enable signal.

3. The semiconductor integrated circuit of claim 1, wherein the current supply unit includes:
a first current source connected between a power voltage and the bit line to supply current to the bit line in response to the test signal; and
a second current source, connected between the power voltage and the complementary bit line, which supplies current to the complementary bit line in response to the test signal.

4. The semiconductor integrated circuit of claim 3, wherein the first current source includes a PMOS transistor having a source to which the power voltage is applied, a gate to which the test signal is input, and a drain connected to the bit line.

5. The semiconductor integrated circuit of claim 3, wherein the second current source includes a PMOS transistor having a source to which the power voltage is applied, a gate to which the test signal is input, and a drain connected to the complementary bit line.

6. A method of detecting soft defects in a static memory cell of a semiconductor integrated circuit including a static memory cell selected by activation of a word line, a bit line connected to a first node of the static memory cell, and a complementary bit line connected to a second node of the static memory cell, the method comprising:
precharging the bit line and the complementary bit line;
supplying current to the bit line and the complementary bit line in response to a test signal during a test mode;
activating the word line; and
sensing and amplifying a voltage difference between the bit line and the complementary bit line in response to a sense enable signal.

7. The method of claim 6, wherein when defects occur in the voltage difference sensing and amplifying step, it is determined that the memory cell is vulnerable to soft defects.
